(19) United States
(12) Patent Application Publication
(10) Pub. No.: US 2024/0175900 A1
(43) Pub. Date: May 30, 2024

(54) PROBE HEAD AND METHOD OF PRODUCING TESTED SEMICONDUCTOR DIE AND VERTICAL PROBE MANUFACTURING METHOD

(71) Applicant: MPI CORPORATION, CHU-PEI CITY (TW)

(72) Inventors: CHIN-YI LIN, CHU-PEI CITY (TW); TZU-YANG CHEN, CHU-PEI CITY (TW); TZU-HAO CHIEN, CHU-PEI CITY (TW); CHAO-SHUN WANG, CHU-PEI CITY (TW); LI-MING FAN, CHU-PEI CITY (TW)

(73) Assignee: MPI CORPORATION, CHU-PEI CITY (TW)

(21) Appl. No.: 18/518,759

(22) Filed: Nov. 24, 2023

(30) Foreign Application Priority Data
Nov. 24, 2022 (TW) 111145056

(51) Int. Cl. G01R 1/073; G01R 1/067; G01R 3/00; H01L 21/66

(52) U.S. Cl. CPC G01R 1/07314; G01R 1/06738; G01R 3/00; H01L 22/10

(57) ABSTRACT

A probe head includes a probe seat, and vertical probes each having a head portion including a head portion installation section with a first width, and a probe tip section including a probe tip contact part with a second width smaller than the first width and a probe tip gradually narrowing part which is located between the head portion installation section and the probe tip contact part, gradually narrows from the first width to the second width, and has a first length smaller than a second length of the probe tip contact part. The head portion installation section protrudes out of a lower surface of the probe seat for a length smaller than the sum of the first and second lengths. The vertical probe is great in current withstanding capability, structural strength and life time, and meets the requirement of probing tiny electrically conductive contacts.

### BACKGROUND OF THE INVENTION

### 1. Field of the Invention

The present invention relates generally to probe heads of probe cards and more particularly, to a probe head, a method of producing a tested semiconductor die, and a vertical probe manufacturing method.

### 2. Description of the Related Art

With the trend of miniaturization of electronic components, some electronic components are provided thereon with electrically conductive contacts with quite small size. Therefore, the probe cards for testing such electronic components should be correspondingly installed with quite thin probes to satisfy the testing requirements.

However, if the diameter of the whole probe is reduced, the resistance of the probe will be highly raised and the structural strength of the probe will be highly reduced. The higher the resistance of the probe, the lower the current withstanding capability of the probe. If the current withstanding capability of the probe is too low, the probe will be liable to be burn out when electrified. Besides, if the structural strength of the probe is too low, the probe will be liable to be worn, bent or even broken when receiving force in the probing process, so that the probe has short life time and thus needs frequent replacement. Therefore, it is a very important subject in this technical field that how to make the probe meet the requirement of probing tiny electrically conductive contacts and raise the life time of the probe under the precondition that the probe has sufficient current withstanding capability.

### SUMMARY OF THE INVENTION

The present invention has been accomplished in view of the above-noted circumstances. It is an objective of the present invention to provide a probe head and a vertical probe manufacturing method, which can make the vertical probe great in current withstanding capability, structural strength and life time, and meet the requirement of probing tiny electrically conductive contacts.

To attain the above objective, the present invention provides a probe head which includes a probe seat, and a plurality of vertical probes. The probe seat includes an upper die unit, and a lower die unit disposed below the upper die unit. The upper die unit includes at least one upper die, and a plurality of upper guiding holes penetrating through the at least one upper die. The lower die unit includes at least one lower die, and a plurality of lower guiding holes penetrating through the at least one lower die. Each of the upper and lower die units has an upper surface and a lower surface. An accommodating space is formed between the lower surface of the upper die unit and the upper surface of the lower die unit. Each of the vertical probes includes a tail portion, a head portion, and a body portion located between the tail portion and the head portion. The tail portion and the head portion are inserted through the upper guiding hole and the lower guiding hole of the probe seat respectively. The body portion is located in the accommodating space. The head portion includes a probe tip section, and a head portion installation section located between the body portion and the probe tip section. The head portion installation section is partially located in the lower guiding hole of the probe seat, and partially protrudes out of the lower surface of the lower die unit. The probe tip section includes a probe tip contact part for contacting an electrically conductive contact of a device under test, and a probe tip gradually narrowing part located between the head portion installation section and the probe tip contact part. The widths of the head portion installation section and the probe tip contact part on a horizontal axis are a first width and a second width respectively. The second width is smaller than the first width. The width of the probe tip gradually narrowing part on the horizontal axis is decreased from the first width to the second width. The second width is larger than or equal to 20 micrometers and smaller than or equal to 70 micrometers (μm). The lengths of the probe tip gradually narrowing part and the probe tip contact part on a vertical axis are a first length and a second length respectively. The second length is larger than the first length. The head portion installation section protrudes out of the lower surface of the lower die unit for a length on the vertical axis, which is a third length. The third length is smaller than the sum of the first length and the second length.

As a result, for the vertical probe in the present invention, the parts thereof other than the probe tip section can be manufactured with the size for sufficient current withstanding capability. The probe tip contact part can be manufactured with a desired size meeting the requirement of probing tiny electrically conductive contacts. In other words, compared with the conventional vertical probe having sufficient current withstanding capability, most of the sections of the vertical probe in the present invention can be maintained with the same size with the conventional vertical probe for being ensured with sufficient current withstanding capability, but the probe tip section gradually narrows to the relatively smaller second width and then extends for the second length such that the free end of the probe tip contact part can meet the requirement of probing tiny electrically conductive contacts. Besides, the probe tip section narrows to the required size gradually, so as to be prevented from highly lowered rigidity due to suddenly reduced width, thereby still retaining sufficient structural strength. In addition, the head portion installation section protrudes out of the lower surface of the lower die unit for the third length, so that the probe tip section is completely located below the lower surface of the lower die unit. Besides, the second length is larger than the first length, and the third length is smaller than the sum of the first and second lengths. Such features make the probe tip contact part have the length capable of being worn to a considerable extent, thereby raising the life time of the vertical probe and lowering the frequency of replacement of the vertical probe. Besides, such features also provide the head portion installation section an appropriate partial length adapted for withdrawing into the lower guiding hole when the vertical probe is moved upwardly during probing. Therefore, it has no need to reserve the partial probe tip contact part for withdrawing into the lower guiding hole when receiving force, so that the whole probe tip contact part is adapted for being worn. In this way, the probe tip contact part is maximized in life time, prevented from being partially unusable and the resulting waste. Besides, it also avoids that if a part of the probe tip section smaller in width than the head portion installation section enters the lower guiding hole, the part may positionally deviate in the lower guiding hole so as to make the free end of the probe tip contact part positionally deviate to cause unstable testing results or even cause failure to the testing. Such probe tip contact part with the second width larger than or equal to 20 μm and smaller than or equal to 70 μm can further meet the requirement of probing tiny electrically conductive contacts, and meanwhile retain sufficient rigidity to attain great structural strength and life time.

Preferably, the cross section of the probe tip contact part is shaped as a circle. The second width is the diameter of the probe tip contact part. As a result, under the condition of meeting the requirement of probing tiny electrically conductive contacts, the probe tip contact part with circular cross section has relatively better structural strength, avoiding the problem that if the cross section is shaped as a rectangle or other shapes, the regions with relatively lower strength is liable to be bent or even broken.

Preferably, the cross section of the head portion installation section is shaped as a circle. The first width is the diameter of the head portion installation section. As a result, when the required width condition is met, the head portion installation section with circular cross section has relatively better structural strength, avoiding the problem that if the cross section is shaped as a rectangle or other shapes, the regions with relatively lower strength is liable to be bent or even broken. The inventor found that the junction where the probe tip gradually narrowing part narrows to the probe tip contact part is the place where the stress is most likely to concentrate to break the probe. In the embodiment wherein the cross section of the probe tip contact part and the cross section of the head portion installation section are both circular, the probe tip contact part and the head portion installation section are homocentric. But the practical processing has processing error, so the probe tip contact part and the head portion installation section are regarded homocentric as long as the processing error of the centers thereof is within 10 μm. The diameter of the probe tip contact part is a reduction of the diameter of the head portion installation section to scale. Viewed from the probe tip contact part toward the head portion installation section, the probe tip contact part is surrounded by the vertical projection of the head portion installation section. In the configuration of this embodiment, the junction where the probe tip gradually narrowing part narrows to the probe tip contact part can make the stress evenly distributed without a concentration at a certain point or a certain position. Compared with the condition that the probe tip contact part and the head portion installation section are not homocentric and not configured to scale, the feature that the cross section of the probe tip contact part and the cross section of the head portion installation section are both circular is effective in preventing the junction where the probe tip gradually narrowing part narrows to the probe tip contact part from being bent or even broken.

In the condition that the probe tip contact part or the head portion installation section has the circular cross section, the other parts of the vertical probe are unlimited to have circular cross sections as well. In particularly, the cross section of the body portion may be shaped as an oblong, so that the cross section of the body portion has two long edges and two short edges. The long edge is longer than the diameter of the head portion installation section. The short edge is shorter than the diameter of the head portion installation section. Such body portion will be elastically deformed in a way of bending toward a specific direction when receiving force. Therefore, a plurality of vertical probes in a same probe head can be ensured that when they receive force, the body portions thereof are elastically deformed in a way of bending toward the same direction, so that the body portions are prevented from the contact with each other and the resulting wearing or short circuit.

Preferably, the first width may be smaller than or equal to 100 μm. Such vertical probe is applicable for the testing requirement of fine pitch, which means the pitch between the adjacent vertical probes can meet the tiny pitch between the electrically conductive contacts of the device under test, and the adjacent vertical probes can be prevented from the contact with each other and the resulting short circuit problem. Besides, under the condition of the aspect ratio suitable for performing the drilling process to the upper and lower die units, the upper and lower die units can be provided with the upper and lower guiding holes corresponding to the size and pitch of such vertical probes so that the probe head can be assembled smoothly.

Preferably, the third length may be smaller than 250 μm. Such size design can satisfy the requirement of the largest over drive, which is also referred to as OD, for the vertical probes of fine probe types whose OD is approximately ranged from 100 μm to 200 μm. Therefore, it can avoid that if the probe tip section enters the lower guiding hole, it may positionally deviate in the lower guiding hole so as to cause unstable testing results or even cause failure to the testing. Besides, it can also maximize the life time of the probe tip contact part.

Preferably, the sum of the first length and the second length, i.e., the length of the probe tip section, may be smaller than or equal to 25 times the second width. Such size design can make the length of the probe tip section and the width of the probe tip contact part, i.e., the second width, attain the optimum structural strength and life time under the condition of meeting the testing requirements.

Preferably, the probe tip gradually narrowing part may have a processing fillet. The radius of the processing fillet is larger than 20 μm. The first length is smaller than 70 μm. As a result, the processing fillet with the radius larger than 20 μm can avoid that the probe tip gradually narrowing part is too short in length, causing the decrease of the width thereof in a too large variation extent, thereby causing the probe tip section low structural strength and the resulting ease of being bent or even broken. Besides, after deciding the length of the probe tip section in consideration of providing the probe tip section great structural strength, the length of the probe tip section equals to the sum of the first length of the probe tip gradually narrowing part and the second length of the probe tip contact part, so the first length decides the second length, which means it also decides the life time of the probe tip contact part. The first length smaller than 70 μm can prevent the first length of the probe tip gradually narrowing part from being too long, so as to make the probe tip contact part have the relatively longer second length and the resulting relatively longer life time.

Preferably, the probe tip gradually narrowing part and the probe tip contact part have a plurality of horizontal abrasion dents arranged vertically; a terminal end segment of the probe tip contact part has a plurality of vertical abrasion dents arranged horizontally. The horizontal abrasion dents can be formed by a grinding process. By the grinding process, it is relatively easier to provide the probe tip gradually narrowing part and the probe tip contact part with the widths and lengths the present invention requires. After the grinding process, the terminal end segment of the probe tip contact part may be further grinded in other grinding manners, such as grinded by abrasive material, thereby provided with the aforementioned vertical abrasion dents. In this way, the terminal end segment of the probe tip contact part can be provided with the width smaller than the second width for probing even smaller electrically conductive contacts or probing the electrically conductive contacts even more precisely.

To attain the above objective, the present invention provides a vertical probe manufacturing method including the steps of:
providing a needle, the needle including a middle section, the width of the middle section on a horizontal axis being a first width;
performing a grinding process to the middle section of the needle to make the middle section include a relatively narrower part and two gradually narrowing parts, which are formed by the grinding process, and two relatively wider parts unprocessed by the grinding process, the two gradually narrowing parts being located between the two relatively wider parts and two ends of the relatively narrower part respectively, the width of each of the relatively wider parts on the horizontal axis being the first width, the width of the relatively narrower part on the horizontal axis being a second width, the second width being smaller than the first width, the width of each of the gradually narrowing parts on the horizontal axis being decreased from the first width to the second width, the second width being larger than or equal to 20 micrometers and smaller than or equal to 70 micrometers; and
cutting the relatively narrower part to make the needle become two vertical probes, each of the vertical probes including a head portion installation section formed from the relatively wider part, a probe tip gradually narrowing part formed from the gradually narrowing part, and a probe tip contact part formed from the relatively narrower part.

By the above-described vertical probe manufacturing method provided by the present invention, it is relatively easier to manufacture the above-described vertical probe provided in the present invention, avoiding the problem that the requirement for the small width and long length of the probe tip contact part is liable to cause a processing failure. Besides, in the vertical probe manufacturing method provided by the present invention, two vertical probes are processed at the same time, so the processing efficiency is great.

Preferably, the above-described vertical probe manufacturing method may further include the steps of:
after the vertical probes are installed in a probe seat, performing a planarization process to a free end of the probe tip contact part of each of the vertical probes in a way that the free ends of the probe tip contact parts of the vertical probes are located at the same elevation on a vertical axis; and
grinding the free ends of the probe tip contact parts of the vertical probes by abrasive material.

The above-described step with the planarization process can make the free ends of the probe tip contact parts of the vertical probes in a same probe head located at the same position of height relatively more precisely, so that the vertical probes in a same probe head will generate equal pressure and be elastically deformed to the same extent by the received force when probing. Besides, the above-described step of grinding by the abrasive material can provide the terminal end segment of the probe tip contact part with the width smaller than the second width for probing even smaller electrically conductive contacts or probing the electrically conductive contacts even more precisely.

Preferably, in the above-described vertical probe manufacturing method, the probe tip gradually narrowing part and the probe tip contact part have a plurality of horizontal abrasion dents arranged vertically, and a terminal end segment of the probe tip contact part has a plurality of vertical abrasion dents arranged horizontally. The horizontal abrasion dents are formed by the grinding process. After the grinding process, the terminal end segment of the probe tip contact part can be further grinded in other grinding manners, such as grinding by abrasive material, thereby provided with the vertical abrasion dents. In this way, the terminal end segment of the probe tip contact part can be provided with the width smaller than the second width for probing even smaller electrically conductive contacts or probing the electrically conductive contacts even more precisely.

Preferably, in the above-described vertical probe manufacturing method, the needle is shaped as a cylinder, and the diameter thereof is the first width. After the grinding process is performed to the middle section of the needle, a flattening process is further performed to two sections of the needle adjacent to the middle section to make the two sections become two flattened sections. The cross section of the flattened section has two long edges and two short edges. The long edge is longer than the first width. The short edge is shorter than the first width. The vertical probe includes a body portion formed from the flattened section. As a result, the cross section of the body portion is approximately shaped as an oblong. Such body portion will be elastically deformed in a way of bending toward a specific direction when receiving force. Therefore, a plurality of vertical probes in a same probe head can be ensured that when they receive force, the body portions thereof are elastically deformed in a way of bending toward the same direction, so that the body portions are prevented from the contact with each other and the resulting wearing or short circuit.

The present invention further provides a method of producing a tested semiconductor die. The method includes the steps of:
obtaining a probe card including a main circuit board, and a probe head disposed on the main circuit board, the probe head including a probe seat and a plurality of vertical probes, the probe seat including an upper die unit, and a lower die unit disposed below the upper die unit, the upper die unit including at least one upper die, and a plurality of upper guiding holes penetrating through the at least one upper die, the lower die unit including at least one lower die, and a plurality of lower guiding holes penetrating through the at least one lower die, each of the upper die unit and the lower die unit having an upper surface and a lower surface, an accommodating space being formed between the lower surface of the upper die unit and the upper surface of the lower die unit, each of the vertical probes including a tail portion, a head portion, and a body portion located between the tail portion and the head portion, the tail portion and the head portion being inserted through the upper guiding hole and the lower guiding hole of the probe seat respectively, the body portion being located in the accommodating space, the head portion including a probe tip section, and a head portion installation section located between the body portion and the probe tip section, the head portion installation section being partially located in the lower guiding hole of the probe seat and partially protruding out of the lower surface of the lower die unit, the probe tip section including a probe tip contact part, and a probe tip gradually narrowing part located between the head portion installation section and the probe tip contact part, the widths of the head portion installation section and the probe tip contact part on a horizontal axis being a first width and a second width respectively, the second width being smaller than the first width, the width of the probe tip gradually narrowing part on the horizontal axis being decreased from the first width to the second width, the second width being larger than or equal to 20 micrometers and smaller than or equal to 70 micrometers, the lengths of the probe tip gradually narrowing part and the probe tip contact part on a vertical axis being a first length and a second length respectively, the second length being larger than the first length, the head portion installation section protruding out of the lower surface of the lower die unit for a length on the vertical axis, which is a third length, the third length being smaller than the sum of the first length and the second length, the vertical probes of the probe head being electrically connected with the main circuit board;
effecting contact between the probe tip contact parts of ones of the vertical probes of the probe card and ones of electrically conductive contacts of the semiconductor die; and
testing the semiconductor die by providing test signals between the ones of the electrically conductive contacts and the ones of the vertical probes through the probe card.

In other words, the aforementioned semiconductor die, during the producing process thereof, is tested through a probe card, and the probe card includes the above-described probe head provided by the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 and FIG. 2 are schematic sectional views of a probe head according to a preferred embodiment of the present invention;

FIG. 3 is a partially enlarged view of FIG. 2;
FIG. 4 is a sectional view taken along the line 4-4 in FIG. 2;
FIG. 5 to FIG. 9 are schematic views of the steps of a vertical probe manufacturing method according to the preferred embodiment of the present invention;
FIG. 10 and FIG. 11 are partially enlarged views of a vertical probe according to the preferred embodiment of the present invention; and
FIG. 12 is a schematic view of a probe card and a device under test in the present invention.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

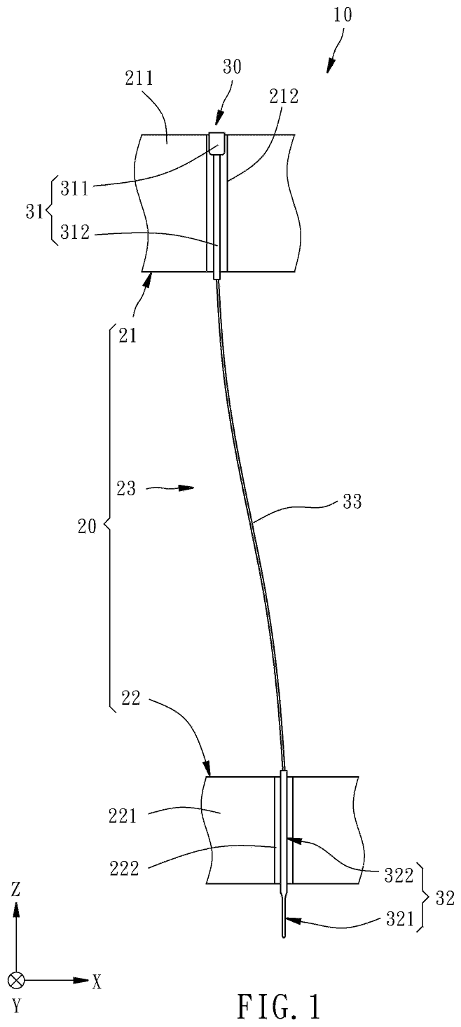

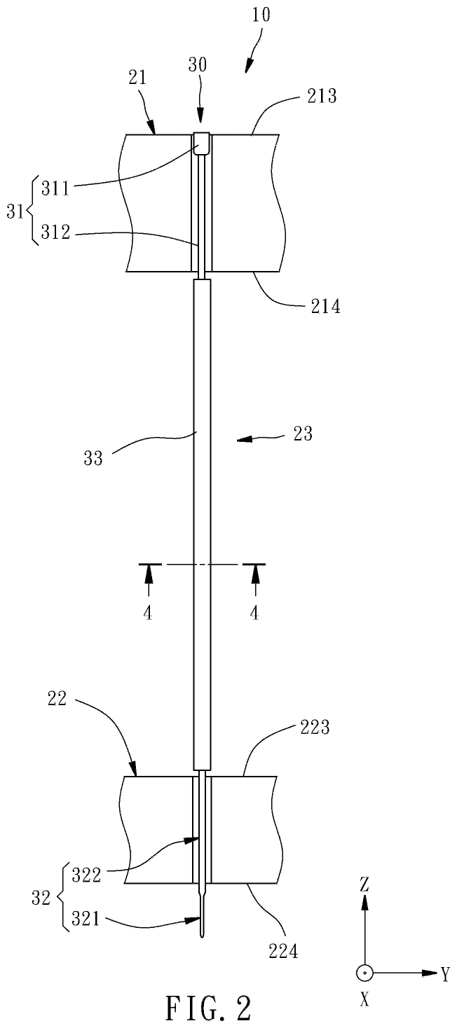

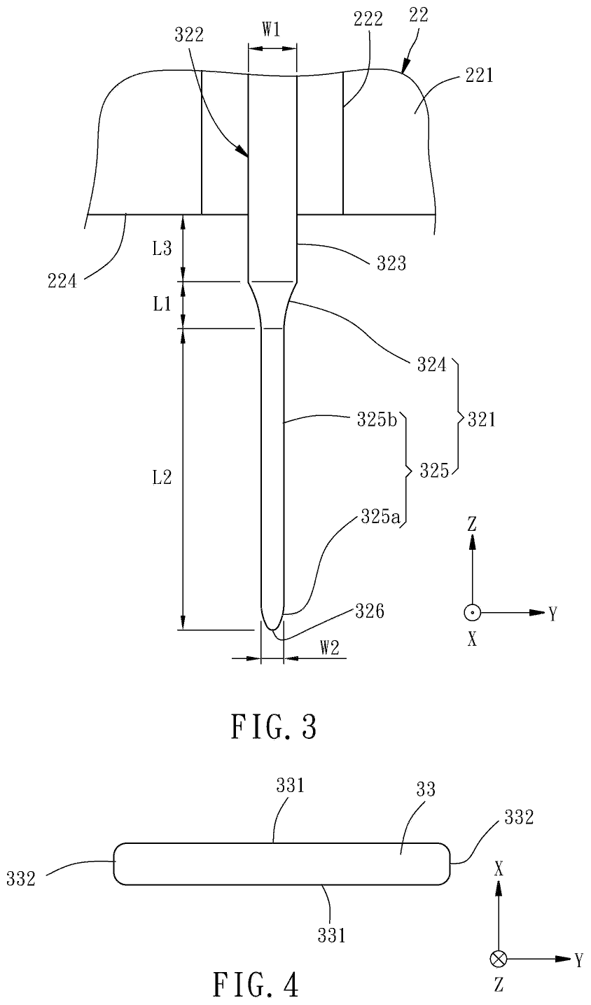

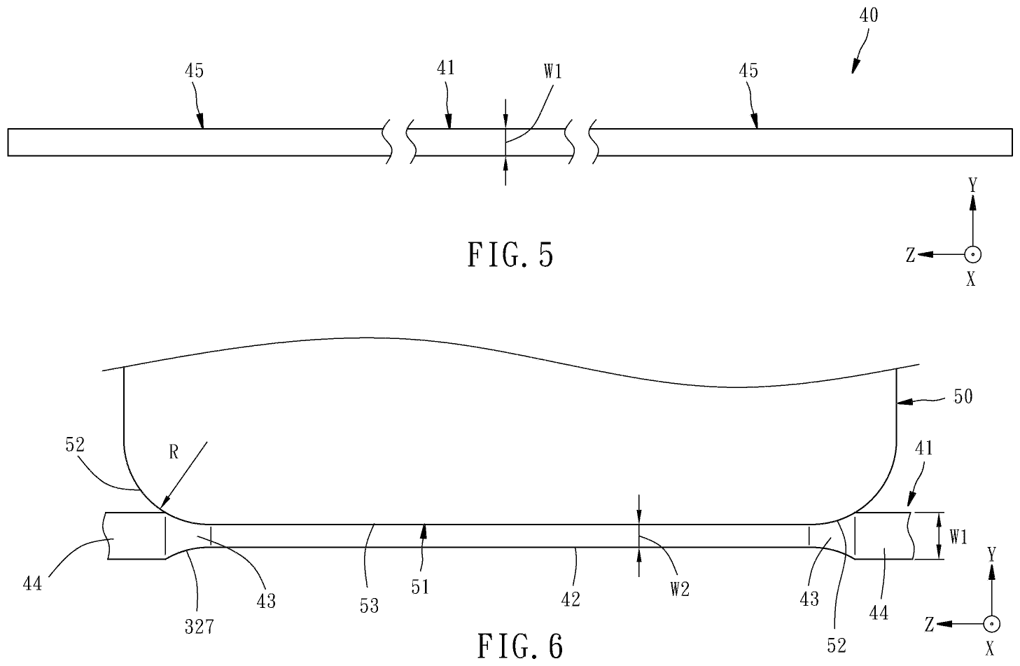

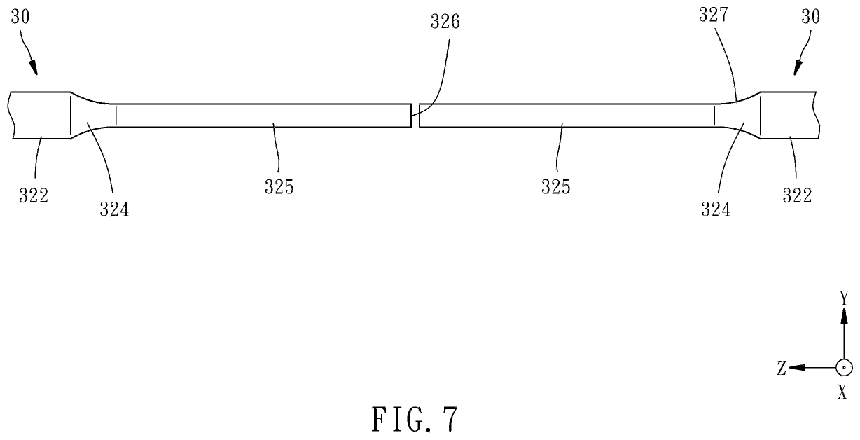

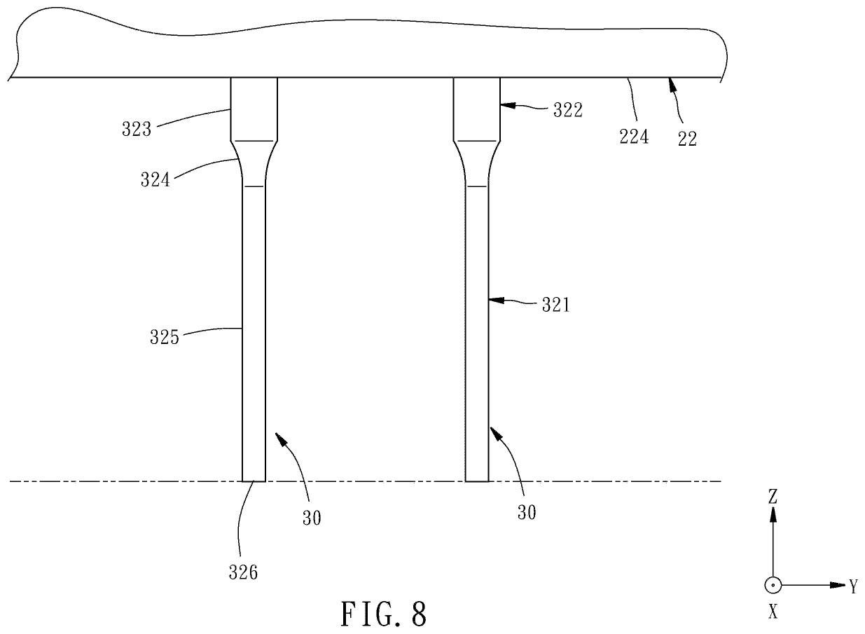

Referring to FIG. 1 and FIG. 2, a probe head 10 according to a preferred embodiment of the present invention includes a probe seat 20, and a plurality of vertical probes 30. For the simplification of the figures and the convenience of illustration, only one vertical probe 30 is shown in FIG. 1 and FIG. 2.

The probe seat 20 includes an upper die unit 21, and a lower die unit 22 disposed below the upper die unit 21. The upper die unit 21 includes at least one upper die 211 and a plurality of upper guiding holes 212. The lower die unit 22 includes at least one lower die 221 and a plurality of lower guiding holes 222. For the simplification of the figures and the convenience of illustration, only one upper guiding hole 212 and only one lower guiding hole 222 are shown in FIG. 1 and FIG. 2. The upper die unit 21 in this embodiment includes only one upper die 211. Each upper guiding hole 212 penetrates through the upper die 211. However, the upper die unit in the present invention may be composed of a plurality of upper dies piled on one another, and each upper guiding hole penetrates through the plurality of upper dies. Similarly, the lower die unit 22 in this embodiment includes only one lower die 221. Each lower guiding hole 222 penetrates through the lower die 221. However, the lower die unit in the present invention may be composed of a plurality of lower dies piled on one another, and each lower guiding hole penetrates through the plurality of lower dies.

The upper die unit 21 has an upper surface 213 and a lower surface 214. The lower die unit 22 has an upper surface 223 and a lower surface 224. An accommodating space 23 is formed between the lower surface 214 of the upper die unit 21 and the upper surface 223 of the lower die unit 22. Specifically speaking, the upper die unit 21 may have a protruding portion (not shown) located at the outer periphery of the upper die unit 21 and protruding downwardly from the lower surface 214. The lower die unit 22 may have a protruding portion (not shown) located at the outer periphery of the lower die unit 22 and protruding upwardly from the upper surface 223. The protruding portions of the upper and lower die units 21 and 22 are connected with each other to form the accommodating space 23 surrounded by the protruding portions. Alternatively, a middle die (not shown) may be further disposed between the upper and lower die units 21 and 22. The middle die is annular in shape and forms the accommodating space 23 surrounded by the middle die. This part is less related to the technical features of the present invention, thereby not shown in the figures for the simplification of the figures and the convenience of illustration.

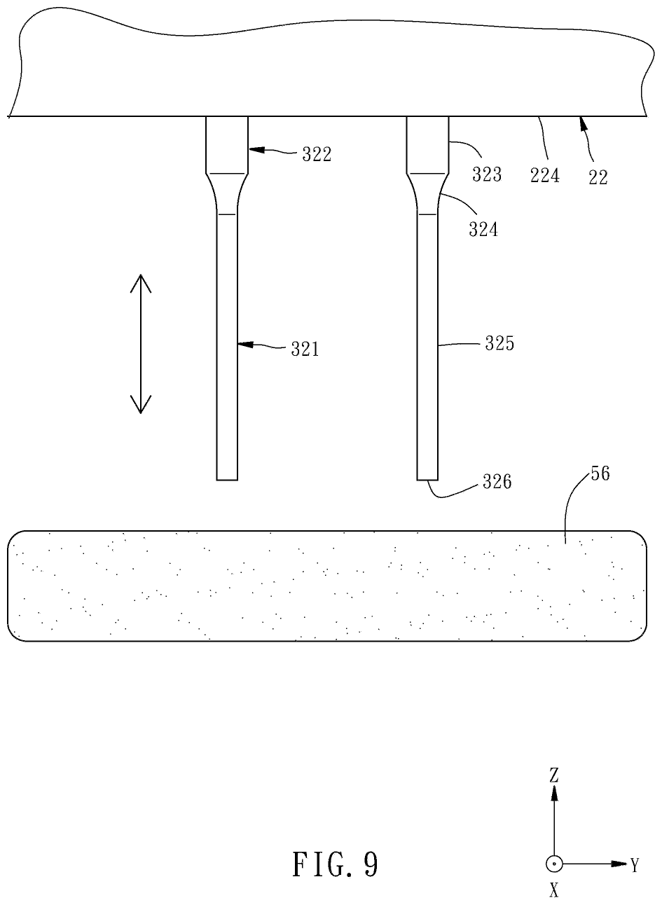

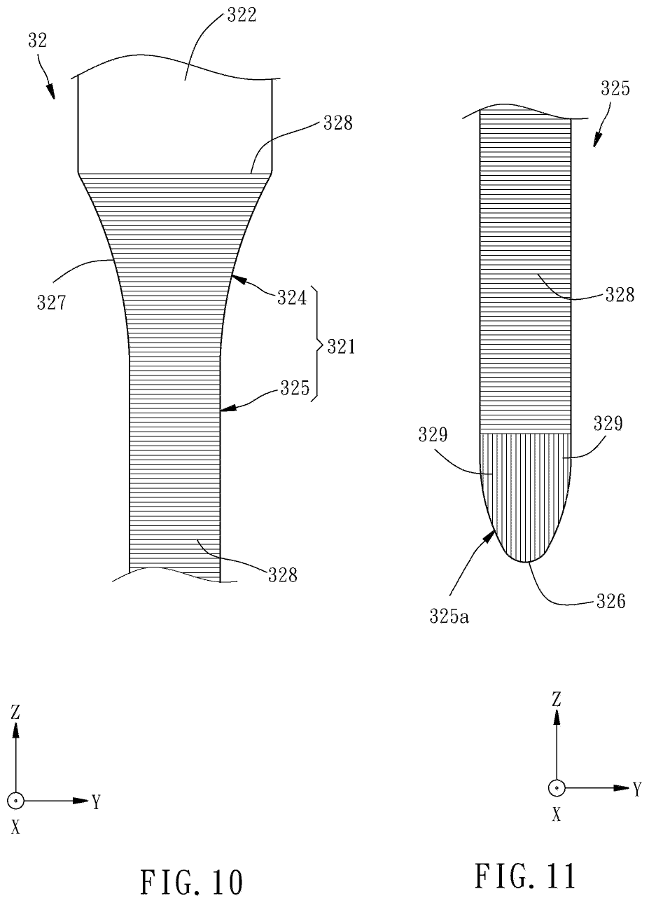

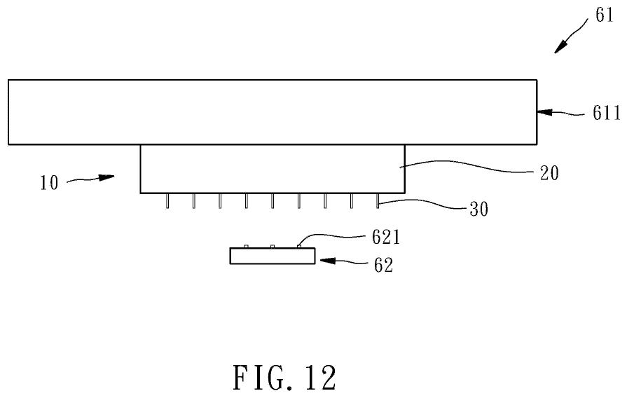

The vertical probe 30 includes a tail portion 31, a head portion 32, and a body portion 33 located between the tail portion 31 and the head portion 32. The tail portion 31 and the head portion 32 are inserted through the upper guiding hole 212 and the lower guiding hole 222 of the probe seat 20 respectively. The body portion 33 is located in the accommodating space 23 of the probe seat 20. Specifically speaking, the tail portion 31 includes a tail portion contact section 311 located at the top end of the tail portion 31, and a tail portion installation section 312 connected between the tail portion contact section 311 and the body portion 33. The head portion 32 includes a probe tip section 321 located below the lower surface 224 of the lower die unit 22, and a head portion installation section 322 connected between the probe tip section 321 and the body portion 33. The tail portion installation section 312 and the head portion installation section 322 of the vertical probe 30 are primarily inserted through the upper and lower guiding holes 212 and 222 of the probe seat 20 respectively. The top end of the tail portion contact section 311 is adapted to be abutted against an electrically conductive contact (not shown) provided on the bottom surface of a main circuit board 611 (as shown in FIG. 12) located above the probe head 10, so that the probe head 10 and the main circuit board 611 compose a probe card 61.

Referring to FIG. 3, the head portion installation section 322 is partially located in the lower guiding hole 222 of the probe seat 20 and partially protrudes out of the lower surface 224 of the lower die unit 22. Specifically speaking, in the status that the vertical probe 30 is installed in the probe seat 20 and doesn't receive force, the head portion installation section 322 has an exposed part 323 protruding from the lower surface 224 of the lower die unit 22, so that the probe tip section 321 is completely located below the lower surface 224 of the lower die unit 22. The probe tip section 321 includes a probe tip gradually narrowing part 324 connected to the head portion installation section 322, and a probe tip contact part 325 connected to the probe tip gradually narrowing part 324. A free end 326 of the probe tip contact part 325 is adapted to contact an electrically conductive contact 621 of a device under test 62 (as shown in FIG. 12) for a tester (not shown) to be electrically connected with the device under test 62 through the aforementioned main circuit board 611 and the vertical probe 30.

The vertical probe manufacturing method provided by the present invention will be described below, and meanwhile the structural features of the probe head 10 and the vertical probe 30 will be further described. The vertical probe manufacturing method provided by the present invention primarily includes the following steps.

a) As shown in FIG. 5, provide a needle 40 made from metal. The needle 40 includes a middle section 41. The width of the middle section 41 on a horizontal axis (Y-axis) is a first width W1.

It should be mentioned here that the directional terms mentioned in the present invention correspond to the orientation of the probe head 10 in use, as shown in FIG. 1 and FIG. 2. The Z-axis is a vertical axis. The X-axis and the Y-axis are both horizontal axes. The first width W1 and a second width W2 to be mentioned below are defined on the Y-axis in this embodiment, but they may be defined on the X-axis. In fact, the needle 40 in this embodiment is shaped as a cylinder, which means the cross section thereof is shaped as a circle, so the width thereof on the Y-axis and the width thereof on the X-axis are both the diameter thereof. In other words, the diameter of the needle 40 is the first width W1.

b) As shown in FIG. 6, perform a grinding process to the middle section 41 of the needle 40 to make the middle section 41 include a relatively narrower part 42 and two gradually narrowing parts 43, which are formed by the grinding process, and two relatively wider parts 44 unprocessed by the grinding process. The two gradually narrowing parts 43 are located between the two relatively wider parts 44 and two ends of the relatively narrower part 42 respectively. The width of each relatively wider part 44 on the horizontal axis (Y-axis) is the above-described first width W1. The width of the relatively narrower part 42 on the horizontal axis (Y-axis) is the second width W2. The second width W2 is smaller than the first width W1. The width of each gradually narrowing part 43 on the horizontal axis (Y-axis) is decreased from the first width W1 to the second width W2.

In this embodiment, this step b) is performed by grinding the middle section 41 of the needle 40 by an outer peripheral surface 51 of a grinding wheel 50 to decrease the width, which is also the diameter in this embodiment, of the partial middle section 41 grinded by the grinding wheel 50. The outer peripheral surface 51 of the grinding wheel 50 includes two round corner portions 52 located at two edges of the outer peripheral surface 51 respectively, and a plane portion 53 located between the two round corner portions 52. The partial middle section 41 of the needle 40 grinded by the plane portion 53 of the grinding wheel 50 is formed into the relatively narrower part 42 with a uniform width, which is the second width W2. The parts of the middle section 41 of the needle 40 grinded by the round corner portions 52 of the grinding wheel 50 are formed into the gradually narrowing parts 43 complementary in shape to the round corner portions 52.

c) Referring to FIG. 6 and FIG. 7, cut the relatively narrower part 42 to make the needle 40 become two vertical probes 30. Each vertical probe 30 includes a head portion installation section 322 formed from the relatively wider part 44, a probe tip gradually narrowing part 324 formed from the gradually narrowing part 43, and a probe tip contact part 325 formed from the relatively narrower part 42.

It can be known from the above description that the vertical probe manufacturing method provided by the present invention is primarily aimed at the probe tip section 321 of the vertical probe 30. The primary structural features of the vertical probe 30 provided in the present invention are located at the probe tip section 321. The shapes of the other parts of the vertical probe 30 and the way for forming them are unlimited. The shape of the body portion 33 of the vertical probe 30 in this embodiment and the way for forming it are instanced in the following description. The shape of the tail portion 31 and the way for forming it are less related to the technical features of the present invention, thereby not detailedly described hereinafter.

In the vertical probe manufacturing method in this embodiment, after the above-described step b) as shown in FIG. 6, a flattening process is further performed to two sections 45 (as shown in FIG. 5) of the needle 40 adjacent to the middle section 41, such as pressing the two sections 45 by a mold, to make the two sections 45 become two flattened sections. After the two vertical probes 30 are formed by the above-described step c) as shown in FIG. 7, the two flattened sections are formed into the body portions 33 of the two vertical probes 30. As shown in FIG. 4, the cross section of each flattened section, i.e., the body portion 33, is shaped as an oblong with four round corners, having two long edges 331 and two short edges 332. Each long edge 331 is longer than the first width W1. Each short edge 332 is shorter than the first width W1. The surface of the body portion 33, on which the above-described short edge 332 is located, is shown in FIG. 1. The surface of the body portion 33, on which the above-described long edge 331 is located, is shown in FIG. 2. Therefore, the body portion 33 looks narrower in FIG. 1 and looks wider in FIG. 2. Such body portion 33 will be elastically deformed in a way of bending toward a specific direction when receiving force. Therefore, a plurality of vertical probes 30 in a same probe head 10 can be ensured that when they receive force, the body portions 33 thereof are elastically deformed in a way of bending toward the same direction, so that the body portions 33 are prevented from the contact with each other and the resulting wearing or short circuit.

However, the cross section of the body portion 33 of the vertical probe 30 in the present invention is unlimited to the above-described shape similar to an oblong having long edges and short edges. For example, it may be shaped as a circle, a square, a trapezoid, and so on. Besides, the needle 40 in the present invention is unlimited to be cylinder-shaped. For example, the cross section of the needle 40 may be shaped as a rectangle, a trapezoid, and so on. Specifically speaking, the needle 40 in the present invention may be a thin cylinder line needle and the whole needle is uniform in diameter, as shown in FIG. 5. The needle 40 is formed into the vertical probe 30 in the present invention by the above-described grinding process, flattening process and/or other processing manners. Alternatively, the needle 40 in the present invention may be manufactured by a microelectromechanical systems manufacturing process, laser cutting, and so on, and may already have the tail portion and the body portion with the required shapes before the above-described steps b) and c) are performed. In addition, the body portion 33 of the vertical probe 30 in the present invention may be directly manufactured with the buckling shape as shown in FIG. 1. Alternatively, the vertical probe 30 in the present invention may be shaped as a straight line when the manufacture thereof is finished. After the vertical probe 30 is installed into the probe seat 20, the upper and lower die units 21 and 22 are moved relative to each other along the X-axis to buckle the body portion 33 of the vertical probe 30 into the buckling shape as shown in FIG. 1.

Further speaking, after a required number of vertical probes 30 for the probe head 10 are manufactured by the above-described step a) to step c), the vertical probes 30 may be firstly installed into the probe seat 20 in a way that the tail portion installation section 312 and the head portion installation section 322 of the vertical probe 30 are inserted through the upper and lower guiding holes 212 and 222 respectively, and then a planarization process is performed to the free end 326 of the probe tip contact part 325 of each vertical probe 30 to make the free ends 326 of the probe tip contact parts 325 of the vertical probes 30 in the probe head 10 the same elevation on the vertical axis (Z-axis), as shown in FIG. 8. In this way, the vertical probes 30 in a same probe head 10 will generate equal pressure and be elastically deformed to the same extent by the received force when probing. At last, the free ends 326 of the probe tip contact parts 325 of the vertical probes 30 are grinded by abrasive material 56, as shown in FIG. 9. The vertical probes 30 and the abrasive material 56 are moved relative to each other along the vertical axis (Z-axis) to make the free ends 326 of the probe tip contact parts 325 of the vertical probes 30 inserted into the abrasive material 56 and grinded along the vertical axis (Z-axis), so as to make a terminal end segment 325a of the probe tip contact part 325 of the vertical probe 30 have the gradually narrowing arc shape as shown in FIG. 3. As a result, as shown in FIG. 10 and FIG. 11, the probe tip gradually narrowing part 324 and the probe tip contact part 325 have a plurality of horizontal abrasion dents 328 produced by the grinding process and arranged vertically, and the terminal end segment 325a of the probe tip contact part 325 has a plurality of vertical abrasion dents 329 produced by the grinding by the abrasive material and arranged horizontally.

It can be known from the above description that, as shown in FIG. 3, the widths of the head portion installation section 322 and the probe tip contact part 325 on the horizontal axis are the first width W1 and the second width W2 respectively. The second width W2 is smaller than the first width W1. The width of the probe tip gradually narrowing part 324 on the horizontal axis is decreased from the first width WI to the second width W2. Besides, the lengths of the probe tip gradually narrowing part 324 and the probe tip contact part 325 on the vertical axis are a first length L1 and a second length L2 respectively. The second length L2 is larger than the first length L1. In addition, the length of the exposed part 323 of the head portion installation section 322 on the vertical axis is a third length L3. The third length L3 is smaller than the sum of the first length L1 and the second length L2. The overall length L4 (as shown in FIG. 2) of the head portion installation section 322, is larger than the sum of the first length L1 and the second length L2. The overall length L4 of the head portion installation section 322 is larger than three times the third length L3. Therefore, the head portion installation section 322 has the sufficient length for being inserted through the lower guiding hole 222, and the head portion installation section 322 has the exposed part 323 protruding out of the lower surface of the lower die unit 22. In other words, the overall length L4 of the head portion installation section 322 is larger than the thickness of the lower die unit 22. If the lower die unit 22 includes only one lower die 221, the overall length L4 of the head portion installation section 322 is larger than the thickness of the lower die 221. If the lower die unit 22 includes a plurality of lower dies 221, the overall length L4 of the head portion installation section 322 is larger than the thickness defined between the upper surface of the top one of the lower dies 221 and the lower surface of the lowest one of the lower dies 221.

As a result, for the vertical probe 30 in the present invention, it can be made from a single metal or metal alloy material by the above-mentioned manufacturing method, such that the tail portion 31, the head portion 32 and the body portion 33 of the vertical probe 30 have a same material. Further, the parts of the vertical probe 30 other than the probe tip section 321 can be manufactured with the size for sufficient current withstanding capability. The probe tip contact part 325 can be manufactured with the size meeting the requirement of probing tiny electrically conductive contacts. In other words, compared with the conventional vertical probe having sufficient current withstanding capability, most of the sections of the vertical probe 30 in the present invention can be maintained with the same size with the conventional vertical probe for being ensured with sufficient current withstanding capability, but the probe tip section 321 gradually narrows to the relatively smaller second width W2 and then extends for the second length L2 such that the free end 326 of the probe tip contact part 325 can meet the requirement of probing tiny electrically conductive contacts. Besides, the probe tip section 321 narrows to the required size gradually, so as to be prevented from highly lowered rigidity due to suddenly reduced width, thereby still retaining sufficient structural strength. Further speaking, the second width W2 is larger than or equal to 20 μm and smaller than or equal to 70 μm, that makes the probe tip contact part 325 meet the requirement of probing tiny electrically conductive contacts even better, and meanwhile retain sufficient rigidity to attain great structural strength and life time.

It is to be mentioned that the vertical probe manufacturing method provided by the present invention is unlimited to include the steps as shown in FIG. 8 and FIG. 9. In other words, the probe tip section 321 of the vertical probe 30 may be shaped as shown in FIG. 7, wherein the width of the free end 326 of the probe tip contact part 325 on the horizontal axis is the second width W2, such that the requirement of probing tiny electrically conductive contacts can be still satisfied to a certain extent. However, the step of grinding by the abrasive material as shown in FIG. 9 can make the width of the terminal end segment 325a of the probe tip contact part 325 smaller than the second width W2, which means the free end 326 is further decreased in width and thus adapted to contact the even smaller electrically conductive contact or contact the electrically conductive contact relatively more precisely.

In this embodiment, the head portion installation section 322 and the probe tip contact part 325 both have cross sections with circular shape. The first width WI is the diameter of the head portion installation section 322. The second width W2 is the diameter of the probe tip contact part 325. As a result, under the condition of meeting the required width condition, the head portion installation section 322 and the probe tip contact part 325 with circular cross sections have relatively better structural strength, avoiding the problem that if the cross section is shaped as a rectangle or other shapes, the regions with relatively lower strength is liable to be bent or even broken.

In addition to the above-described structural features and effects, as shown in FIG. 3, the head portion installation section 322 of the vertical probe 30 in the present invention has the exposed part 323, so that the probe tip section 321 is completely located below the lower surface 224 of the lower die unit 22. Besides, the second length L2 of the probe tip contact part 325 is larger than the first length L1 of the probe tip gradually narrowing part 324, and the third length L3 of the exposed part 323 is smaller than the sum of the first and second lengths L1 and L2. Such features make the probe tip contact part 325 have the length capable of being worn to a considerable extent, thereby raising the life time of the vertical probe 30 and lowering the frequency of replacement of the vertical probe 30. Specifically speaking, the probe tip contact part 325 shown in FIG. 3 includes a to-be-worn segment 325b, which is located between the probe tip gradually narrowing part 324 and the terminal end segment 325a. The to-be-worn segment 325b extends from the probe tip gradually narrowing part 324 to the terminal end segment 325a in a uniform width manner with the second width W2. When the terminal end segment 325a is worn to a certain extent, the grinding step as shown in FIG. 9 can be performed again to make a part of the to-be-worn segment 325b become a new terminal end segment 325a. Alternatively, if the probe tip section 321 is shaped as shown in FIG. 7, the whole probe tip contact part 325 is the to-be-worn segment. As a result, after the probe tip contact part 325 is gradually worn from the free end 326 thereof, it still has a certain length for probing tiny electrically conductive contacts.

Further speaking, when the electrically conductive contacts of the device under test are probed by the vertical probes 30, the vertical probes 30 have to absorb the height differences between the electrically conductive contacts of the device under test, so the vertical probe 30 is usually provided with an over drive, which is also referred to as OD. That means, when the electrically conductive contact of the device under test is probed by the vertical probe 30, the probe tip section 321 receives a reacting force so as to move toward the lower guiding hole 222 for the distance called over drive. Originally, there is only the head portion installation section 322 located in the lower guiding hole 222. The relative width between the head portion installation section 322 and the lower guiding hole 222 is fixed. If the probe tip section 321 is moved upwardly by the received force to enter the lower guiding hole 222, the relative width between the lower guiding hole 222 and the partial probe located therein will have a change. This change may make the probe tip section 321 move relative to the lower guiding hole 222, so as to deviate the free end 326 of the probe tip contact part 325 from its original position. The head portion installation section 322 in the present invention has the exposed part 323 with the third length L3. When the head portion 32 is moved upwardly when probing the device under test, the exposed part 323 of the head portion installation section 322 can withdraw into the lower guiding hole 222, so that the whole probe tip section 321 is still located out of the lower guiding hole 222. Therefore, it has no need to reserve the partial probe tip contact part 325 for withdrawing into the lower guiding hole 222 when receiving force, so that the whole probe tip contact part 325 is adapted for being worn. In this way, the probe tip contact part 325 is maximized in life time, prevented from being partially unusable and the resulting waste. Besides, the partial probe entering the lower guiding hole 222 can be maintained with a fixed width, avoiding that if the probe tip section 321 smaller in width than the head portion installation section 322 enters the lower guiding hole 222, the probe tip section 321 may positionally deviate in the lower guiding hole 222 so as to make the free end 326 of the probe tip contact part 325 positionally deviate to cause unstable testing results or even cause failure to the testing.

In order to make the above-described effects of the present invention even better, the third length L3 may be smaller than 250 μm. Such size design can satisfy the requirement of the largest OD for the vertical probes of fine probe types whose OD is approximately ranged from 100 μm to 200 μm, thereby capable of avoiding that if the probe tip section 321 enters the lower guiding hole 222, it may positionally deviate in the lower guiding hole 222 so as to cause unstable testing results or even cause failure to the testing. Besides, it can also maximize the life time of the probe tip contact part 325. In addition, the sum of the first length L1 and the second length L2, i.e., the length of the probe tip section 321, may be smaller than or equal to 25 times the second width W2. Such size design can make the length of the probe tip section 321 and the width of the probe tip contact part 325, i.e., the second width W2, attain the optimum structural strength and life time under the condition of meeting the testing requirements.

Furthermore, the probe tip gradually narrowing part 324 in this embodiment has a processing fillet 327 as shown in FIG. 6, which is a concave arc surface formed on the probe tip gradually narrowing part 324 by the round corner portion 52 of the grinding wheel 50. The radius R of the processing fillet 327 equals to the radius of curvature of the round corner portion 52 of the grinding wheel 50. The radius R of the processing fillet 327 may be larger than 20 μm, and the first length L1 is smaller than 70 μm. As a result, the processing fillet 327 with the radius R larger than 20 μm can avoid that the probe tip gradually narrowing part 324 is too short in length, causing the decrease of the width thereof in a too large variation extent, thereby causing the probe tip section 321 low structural strength and the resulting ease of being bent or even broken. Besides, the length of the probe tip section 321 equals to the sum of the first length L1 of the probe tip gradually narrowing part 324 and the second length L2 of the probe tip contact part 325. Therefore, after deciding the length of the probe tip section 321 in consideration of providing the probe tip section 321 great structural strength, the first length L1 decides the second length L2, which means it also decides the life time of the probe tip contact part 325. The first length L1 smaller than 70 μm can prevent the first length L1 of the probe tip gradually narrowing part 324 from being too long, so as to make the probe tip contact part 325 have the relatively longer second length L2 and the resulting relatively longer life time.

In another aspect, the first width W1 of the head portion installation section 322 may be smaller than or equal to 100 μm. Such vertical probe 30 is applicable to the testing requirement of fine pitch, which means the pitch between the adjacent vertical probes 30 can meet the tiny pitch between the electrically conductive contacts of the device under test, and the adjacent vertical probes 30 can be prevented from the contact with each other and the resulting short circuit problem. Besides, under the condition of the aspect ratio suitable for performing the drilling process to the upper and lower die units 21 and 22, the upper and lower die units 21 and 22 can be provided with upper and lower guiding holes 212 and 222 corresponding to the size and pitch of such vertical probe 30 so that the probe head 10 can be assembled smoothly.

In conclusion, the vertical probe 30 provided in the present invention is great in current withstanding capability, structural strength and life time, and can meet the requirement of probing tiny electrically conductive contacts. It is relatively easier to manufacture the vertical probe 30 provided in the present invention by the vertical probe manufacturing method provided by the present invention, avoiding the problem that the requirement for the small width and long length of the probe tip contact part 325 is liable to cause a processing failure. Besides, in the vertical probe manufacturing method provided by the present invention, two vertical probes 30 are processed at the same time, so the processing efficiency is great.

As described above, the probe head 10 provided by the present invention is applied to a probe card 61 for testing a device under test 62, as shown in FIG. 12. For example, the device under test 62 may be a semiconductor die, so the present invention further provides a method of producing a tested semiconductor die. The method includes the following step a) to step c).

a) Obtain a probe card 61 including a main circuit board 611, and a probe head 10 disposed on the main circuit board 611. The vertical probes 30 of the probe head 10 are electrically connected with the main circuit board 611.

For the simplification of the figure and the convenience of illustration, each component shown in FIG. 12 is only drawn in a simplified schematic manner. The structure of the probe head 10 is as described above and as shown in FIG. 1 to FIG. 11, thereby not repeatedly described hereinafter. In FIG. 12, the probe head 10 is directly disposed on the bottom surface of the main circuit board 611. The tail portion contact sections 311 of the vertical probes 30 are electrically connected with electrically conductive contacts (not shown) provided on the bottom surface of the main circuit board 611 directly. However, a space transformer (not shown) may be further disposed between the probe head 10 and the main circuit board 611, so that the tail portion contact sections 311 of the vertical probes 30 are electrically connected with the electrically conductive contacts provided on the bottom surface of the main circuit board 611 indirectly through the space transformer.

b) Effect contact between the probe tip contact parts 325 of ones of the vertical probes 30 of the probe card 61 and ones of electrically conductive contacts 621 of the semiconductor die 62.

Specifically speaking, the semiconductor die 62 and/or the probe card 61 is moved by a moving device (not shown), which means the semiconductor die 62 may be unmoved and the probe card 61 is moved, or the probe card 61 may be unmoved and the semiconductor die 62 is moved, or they are both moved. The vertical probes 30 are firstly positioned correspondingly to the electrically conductive contacts 621 of the semiconductor die 62 along the vertical axis, and then the probe card 61 and the semiconductor die 62 are moved relative to each other to approach each other along the vertical axis to make the free ends 326 of the probe tip contact parts 325 of the vertical probes 30 in contact with the electrically conductive contacts 621 of the semiconductor die 62, so that the electrically conductive contacts 621 of the semiconductor die 62 are electrically connected with the vertical probes 30.

c) Test the semiconductor die 62 by providing test signals between the ones of the electrically conductive contacts 621 and the ones of the vertical probes 30 through the probe card 61.

Specifically speaking, the main circuit board 611 of the probe card 61 is adapted to be electrically connected to a tester (not shown). The test signals are provided by the tester and transmitted to the electrically conductive contacts 621 of the semiconductor die 62 through the main circuit board 611 and the vertical probes 30, and then transmitted from the electrically conductive contacts 621 of the semiconductor die 62 back to the tester through the vertical probes 30 and the main circuit board 611, such that the semiconductor die 62 can be tested.

The invention being thus described, it will be obvious that the same may be 5 varied in many ways. Such variations are not to be regarded as a departure from the spirit and scope of the invention, and all such modifications as would be obvious to one skilled in the art are intended to be included within the scope of the following claims.

What is claimed is:

1. A probe head comprising:
a probe seat comprising an upper die unit, and a lower die unit disposed below the upper die unit, the upper die unit comprising at least one upper die, and a plurality of upper guiding holes penetrating through the at least one upper die, the lower die unit comprising at least one lower die, and a plurality of lower guiding holes penetrating through the at least one lower die, each of the upper die unit and the lower die unit having an upper surface and a lower surface, an accommodating space being formed between the lower surface of the upper die unit and the upper surface of the lower die unit; and
a plurality of vertical probes, each of the vertical probes comprising a tail portion, a head portion, and a body portion located between the tail portion and the head portion, the tail portion and the head portion being inserted through the upper guiding hole and the lower guiding hole of the probe seat respectively, the body portion being located in the accommodating space;
wherein the head portion comprises a probe tip section, and a head portion installation section located between the body portion and the probe tip section; the head portion installation section is partially located in the lower guiding hole of the probe seat, and partially protrudes out of the lower surface of the lower die unit; the probe tip section comprises a probe tip contact part for contacting an electrically conductive contact of a device under test, and a probe tip gradually narrowing part located between the head portion installation section and the probe tip contact part; widths of the head portion installation section and the probe tip contact part on a horizontal axis are a first width and a second width respectively; the second width is smaller than the first width; a width of the probe tip gradually narrowing part on the horizontal axis is decreased from the first width to the second width; the second width is larger than or equal to 20 micrometers and smaller than or equal to 70 micrometers; lengths of the probe tip gradually narrowing part and the probe tip contact part on a vertical axis are a first length and a second length respectively; the second length is larger than the first length; the head portion installation section protrudes out of the lower surface of the lower die unit for a length on the vertical axis, which is a third length; the third length is smaller than a sum of the first length and the second length; a cross section of the probe tip contact part is shaped as a circle; the second width is a diameter of the probe tip contact part.

2. The probe head as claimed in claim 1, wherein a cross section of the head portion installation section is shaped as a circle; the first width is a diameter of the head portion installation section.

3. The probe head as claimed in claim 2, wherein a cross section of the body portion has two long edges and two short edges; each of the long edges is longer than the diameter of the head portion installation section; each of the short edges is shorter than the diameter of the head portion installation section.

4. The probe head as claimed in claim 1, wherein the first width is smaller than or equal to 100 micrometers.

5. The probe head as claimed in claim 1, wherein the third length is smaller than 250 micrometers.

6. The probe head as claimed in claim 1, wherein the sum of the first length and the second length is smaller than or equal to 25 times the second width.

7. The probe head as claimed in claim 1, wherein the probe tip gradually narrowing part has a processing fillet; a radius of the processing fillet is larger than 20 micrometers; the first length is smaller than 70 micrometers.

8. The probe head as claimed in claim 1, wherein the probe tip gradually narrowing part and the probe tip contact part have a plurality of horizontal abrasion dents arranged vertically; a terminal end segment of the probe tip contact part has a plurality of vertical abrasion dents arranged horizontally.

9. A method of producing a tested semiconductor die, the method comprising the steps of:
obtaining a probe card comprising a main circuit board, and a probe head disposed on the main circuit board, the probe head comprising a probe seat and a plurality of vertical probes, the probe seat comprising an upper die unit, and a lower die unit disposed below the upper die unit, the upper die unit comprising at least one upper die, and a plurality of upper guiding holes penetrating through the at least one upper die, the lower die unit comprising at least one lower die, and a plurality of lower guiding holes penetrating through the at least one lower die, each of the upper die unit and the lower die unit having an upper surface and a lower surface, an accommodating space being formed between the lower surface of the upper die unit and the upper surface of the lower die unit, each of the vertical probes comprising a tail portion, a head portion, and a body portion located between the tail portion and the head portion, the tail portion and the head portion being inserted through the upper guiding hole and the lower guiding hole of the probe seat respectively, the body portion being located in the accommodating space, the head portion comprising a probe tip section, and a head portion installation section located between the body portion and the probe tip section, the head portion installation section being partially located in the lower guiding hole of the probe seat and partially protruding out of the lower surface of the lower die unit, the probe tip section comprising a probe tip contact part, and a probe tip gradually narrowing part located between the head portion installation section and the probe tip contact part, widths of the head portion installation section and the probe tip contact part on a horizontal axis being a first width and a second width respectively, the second width being smaller than the first width, a width of the probe tip gradually narrowing part on the horizontal axis being decreased from the first width to the second width, the second width being larger than or equal to 20 micrometers and smaller than or equal to 70 micrometers, lengths of the probe tip gradually narrowing part and the probe tip contact part on a vertical axis being a first length and a second length respectively, the second length being larger than the first length, the head portion installation section protruding out of the lower surface of the lower die unit for a length on the vertical axis, which is a third length, the third length being smaller than a sum of the first length and the second length, the vertical probes of the probe head being electrically connected with the main circuit board;
effecting contact between the probe tip contact parts of ones of the vertical probes of the probe card and ones of electrically conductive contacts of the semiconductor die; and
testing the semiconductor die by providing test signals between the ones of the electrically conductive contacts and the ones of the vertical probes through the probe card.

10. A vertical probe manufacturing method comprising the steps of:
providing a needle, the needle comprising a middle section, a width of the middle section on a horizontal axis being a first width;
performing a grinding process to the middle section of the needle to make the middle section comprise a relatively narrower part and two gradually narrowing parts, which are formed by the grinding process, and two relatively wider parts unprocessed by the grinding process, the two gradually narrowing parts being located between the two relatively wider parts and two ends of the relatively narrower part respectively, a width of each of the relatively wider parts on the horizontal axis being the first width, a width of the relatively narrower part on the horizontal axis being a second width, the second width being smaller than the first width, a width of each of the gradually narrowing parts on the horizontal axis being decreased from the first width to the second width, the second width being larger than or equal to 20 micrometers and smaller than or equal to 70 micrometers; and
cutting the relatively narrower part to make the needle become two vertical probes, each of the vertical probes comprising a head portion installation section formed from the relatively wider part, a probe tip gradually narrowing part formed from the gradually narrowing part, and a probe tip contact part formed from the relatively narrower part.

11. The vertical probe manufacturing method as claimed in claim 10, further comprising the steps of:
after the vertical probes are installed in a probe seat, performing a planarization process to a free end of the probe tip contact part of each of the vertical probes in a way that the free ends of the probe tip contact parts of the vertical probes are located at a same elevation on a vertical axis; and
grinding the free ends of the probe tip contact parts of the vertical probes by abrasive material.

12. The vertical probe manufacturing method as claimed in claim 10, wherein the needle is shaped as a cylinder, and a diameter thereof is the first width; after the grinding process is performed to the middle section of the needle, a flattening process is further performed to two sections of the needle adjacent to the middle section to make the two sections become two flattened sections; a cross section of each of the flattened sections has two long edges and two short edges; each of the long edges is longer than the first width; each of the short edges is shorter than the first width; each of the vertical probes comprises a body portion formed from the flattened section.

13. The vertical probe manufacturing method as claimed in claim 10, wherein the probe tip gradually narrowing part and the probe tip contact part have a plurality of horizontal abrasion dents arranged vertically; a terminal end segment of the probe tip contact part has a plurality of vertical abrasion dents arranged horizontally.

14. The vertical probe manufacturing method as claimed in claim 10, wherein the first width is smaller than or equal to 100 micrometers; lengths of the probe tip gradually narrowing part and the probe tip contact part on a vertical axis are a first length and a second length respectively; a sum of the first length and the second length is smaller than or equal to 25 times the second width; the probe tip gradually narrowing part has a processing fillet; a radius of the processing fillet is larger than 20 micrometers; the first length is smaller than 70 micrometers.
